(19) United States
(12) Patent Application Publication
(10) Pub. No.: US 2002/0171152 A1
(43) Pub. Date: Nov. 21, 2002

(54) Flip-chip-type semiconductor device and manufacturing method thereof

(75) Inventor: Takashi Miyazaki, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/147,903

(22) Filed: May 20, 2002

(30) Foreign Application Priority Data
May 18, 2001 (JP) 2001-150171

(51) Int. Cl. H01L 23/48; H01L 23/52; H01L 29/40

(52) U.S. Cl. 257/778; 257/738; 257/737

(57) ABSTRACT

There are provided a flip-chip-type semiconductor device and a manufacturing method thereof that can sufficiently reduce stress generated in the connecting portions between a semiconductor chip and a mounting substrate, and can achieve excellent mounting reliability.

A pad electrode is selectively formed on the surface of a semiconductor chip, conductive post including at least two conductive layers, which have different materials each other, on the pad electrode, and bump electrode is formed on the conductive post. The bump electrode is connected to a mounting substrate, and the pad electrode is electrically connected to the mounting substrate.

The conductive post is formed by forming first conductive layer and second conductive layer on the first conductive layer selectively on a base material (temporary substrate), electrically connecting the first and second conductive layers to the pad electrode, and thereafter separating the temporary substrate from the first conductive layer.

### BACKGROUND OF THE INVENTION

1. Field of the Invention

The present invention relates to a semiconductor device and a method for the manufacturing method thereof, and more specifically to a flip-chip-type semiconductor device that is electrically and mechanically connected to a mounting object such as a mounting substrate through connecting members such as solder bumps, and a manufacturing method thereof.

2. Description of the Related Art

In general, since a flip-type semiconductor device using solder bumps as connecting terminals for mounting (i.e., connecting members) can arrange the bumps on optional locations not only around a semiconductor chip, a large number of external connecting terminals can be easily provided by arranging the solder bumps in an area-array pattern. Therefore, such a flip-type semiconductor device is widely used in recent highly integrated, high-density integrated circuits.

FIG. 14 shows an example of conventional flip-type semiconductor devices 100.

The semiconductor device 100 includes a semiconductor chip 101 having a plurality of pad electrodes (not shown) arranged on the surface thereof in an area-array pattern, and a plurality of solder bumps 102 each formed on each of the pad electrodes.

FIG. 15 shows a state wherein the semiconductor device 100 is mounted on a mounting substrate 103 having a multi-layer wiring structure.

The mounting substrate 103 has a plurality of pad electrodes (not shown) arranged so as to correspond to each of the solder bumps 102 of the semiconductor device 100. To each of the pad electrodes of the mounting substrate 103, a corresponding solder bump 102 of the semiconductor device 100 is joined.

The semiconductor device 100 is normally mounted on the mounting substrate 103 by melting and solidifying the solder bumps 102 in the infrared radiation (IR) reflow process using a flux, and electrically and mechanically connecting the solder bumps 102 to the pad electrodes of the mounting substrate 103.

In an operating state, the semiconductor device 100 is subjected to heat that is generated by itself or by other devices. For this reason, such a stress that is generated due to difference in the coefficient of linear expansion (coefficient of thermal expansion) between the mounting substrate 103 and the semiconductor chip 101, is applied to connecting portions of the solder bumps 102. This stress may produce cracks between the solder bumps 102 and the pad electrodes of the semiconductor chip 101, and arise a problem that the electrical connection between the semiconductor chip 101 and the mounting substrate 103 is deteriorated. Thus, conventional semiconductor devices have a problem of low mounting reliability (particularly, temperature cycle characteristics). Consequently, various measures have been proposed to solve such problems.

For example, there is a method using ceramic materials, such as AlN (aluminum nitride), mullite, and glass ceramics, those of which are relatively close to silicon in the coefficient of linear expansion, as the base material of the mounting substrate 103. According to this method, difference in the coefficient of linear expansion between the mounting substrate 103 and the semiconductor chip 101 can be reduced, and mounting reliability can be improved.

On the other hand, as a technique for improving mounting reliability while using a mounting substrate of a large coefficient of linear expansion, a method wherein an under-fill resin is allowed to intervene between a semiconductor chip 101 and a mounting substrate 103, has been studied actively in recent years. According to this method, since shearing stress acting to the connecting portions of solder bumps 102 is dispersed by the under-fill resin, mounting reliability is improved. Moreover, there is another advantage of reducing the manufacturing costs of the mounting substrate 103 because a relatively inexpensive organic material can be used as the base material of the mounting substrate 103.

In the meanwhile, since a large integrated circuit (LSI) is formed on a semiconductor chip 101, the semiconductor chip 101 is generally expensive. Therefore, if a semiconductor device 100 is found defective caused by a portion other than the semiconductor chip 101 in testing and selecting processes conducted after mounting the semiconductor device 100 on a mounting substrate 103, it is desired to remove the good semiconductor device 100 once mounted, and reuse it. The removal of a semiconductor device 100 once mounted from the mounting substrate 103 is known as “repair”.

FIG. 16 shows a general repairing method wherein the semiconductor device 100 of FIG. 14 is to be repaired.

First, a heating and sucking tool 111 for repair having a built-in heater 112 is contacted to the back of the semiconductor chip 101, and then, the air in the suction hole 113 of the heating and sucking tool 111 is sucked in the direction of the arrow to attract the semiconductor chip 101 to the heating and sucking tool 111.

Next, the semiconductor device 100 is heated with a heater 112 while attracting the semiconductor chip 101. This heating causes solder bumps 102 to melt slowly.

Furthermore, while maintaining heating and sucking, the heating and sucking tool 111 is pulled up in the direction of the arrows A to separate the solder bumps 102 from the electrodes of the mounting substrate 103, and the semiconductor device 100 is removed from the mounting substrate 103.

In another repairing method, not only the semiconductor chip 101 is heated, but also the mounting substrate 103 may be heated.

As described above, a conventional flip-chip-type semiconductor device 100 shown in FIG. 14 has a problem in that stress generated in the connecting portions of solder bumps 102 when the device is heated is large, and mounting reliability becomes poor. Therefore, it is required to improve mounting reliability to use a ceramic material for the mounting substrate 103, or to allow an under-fill resin between the semiconductor chip 101 and the mounting substrate 103.

However, the use of a ceramic material for the mounting substrate 103 is disadvantageous in that the costs of the mounting substrate 103 elevate because the ceramic material is expensive. Therefore, the applicable range is limited to high-end machines, such as super computers and large computers.

Also, when an under-fill resin is allowed to intervene between the semiconductor chip 101 and the mounting substrate 103, there is a disadvantage that the semiconductor chip 101 is easily peeled off from the mounting substrate 103 after mounting. That is, if voids are present in the under-fill resin, or if the adhesion of each of the interfaces between the semiconductor chip 101 and the mounting substrate 103, and the under-fill resin is weak, the interfacial peeling off phenomenon of the under-fill resin is induced when moisture-absorbing reflow is performed after mounting. Since such peeling off increases defective rates, the costs cannot be reduced sufficiently even if an inexpensive organic material is used in the mounting substrate 103.

Therefore, conventional flip-chip-type semiconductor devices 100 have a problem of difficulty to elevate mounting reliability while reducing the costs.

Furthermore, in conventional flip-chip-type semiconductor devices 100, heating during repairing and stress accompanying the heating may damage the active region of the semiconductor chip 101. When a passivation film is formed on the surface of the semiconductor chip 101 to protect the active region, the passivation film may be damaged. Therefore, the semiconductor chip 101 may become defective.

When an under-fill resin is allowed to intervene between the semiconductor chip 101 and the mounting substrate 103, repair itself is substantially impossible. Consequently, not only the semiconductor device 100, but also the mounting substrate 103 and the peripheral devices mounted on the mounting substrate 103 will become defective.

Therefore, conventional semiconductor devices have a problem that cost reduction by repair is difficult.

Also, another prior art of a flip-chip-type semiconductor device is disclosed in Japanese Patent Laid-Open No. 2000-124168. In this prior art, via posts are formed on the electrodes of a semiconductor chip by copper plating, an epoxy resin is formed on the upper surface of the semiconductor chip and the via posts, then the upper surfaces of the via posts are exposed, and solder bumps are formed on the exposed upper surfaces of the via posts. In this prior art, it is considered that stress exerted on each of the semiconductor chip and the mounting substrate is relieved to some extent by the via posts formed on the electrodes of a semiconductor chip.

However, when requirement to reduce stress arises, such as when the via posts must be narrowed due to increase in the density of the via posts, and the size of solder bumps formed thereon is reduced accordingly, or when the material for the mounting substrate is changed, this prior art has a problem of difficulty to cope with the requirement, resulting in lowered mounting reliability. That is, even if effort to increase the height of via posts are made to relieve the stress, there is limitation in the height of via posts because this prior art uses a method for forming via posts directly on the electrode pads using copper plating. Although it is not shown herein, in order to form via posts by plating, a mask having holes of the size of the via post to be formed is first formed, and plating is performed so as to fill the holes. Although the mask is normally formed using a resist, in order to form holes having a favorable shape, the thickness of the resist cannot be so increased due to the restriction of the exposure technology. Therefore, since the height of the via posts is limited to the thickness of the resist film, the height of the via posts cannot be much increased. Thus, mounting reliability may be lowered.

### SUMMARY OF THE INVENTION

Therefore, an object of the present invention is to provide a flip-chip-type semiconductor device and a manufacturing method thereof that can sufficiently reduce stress generated in the connecting portion of a semiconductor chip and a mounting substrate.

Another object of the present invention is to provide a flip-chip-type semiconductor device and a manufacturing method thereof that can give excellent mounting reliability while reducing the costs.

According to the present invention, there is provided a semiconductor device, which comprises a semiconductor chip having pad electrode selectively formed on the surface thereof, a conductive post provided on the pad electrode, and a bump electrode formed on one end surface of the conductive post, the conductive post comprising at least first and second conductive layers, and the first conductive layer being composed of a different material from the material of the second conductive layer.

According to the semiconductor device of the present invention, when the semiconductor chip is mounted on a mounting substrate, a distance between the mounting substrate and the semiconductor chip becomes large by the conductive post. Further, since the conductive post includes at least two conductive layers, each of the materials of the conductive layers can be adequately changed to meet the thermal expansion of each of the semiconductor chip side and the mounting substrate side. Therefore, stress acting to each of connecting portions between the conductive post and each of the semiconductor chip and the mounting substrate is sufficiently reduced, and thereby mounting reliability and ease of repairing are improved.

Further, according to the present invention, there is provided a method of manufacturing a semiconductor device, which comprises

(a) selectively forming conductive post on a base material,

(b) placing a semiconductor chip having a pad electrode on the surface thereof so that the pad electrode faces one end surface of the conductive post to electrically connect the pad electrode to the conductive post,

(c) separating the base material from the conductive post to expose the other end surface of the conductive post, and

(d) forming a bump electrode on the exposed other end surface of the conductive post.

According to the method of the present invention, the semiconductor device, which has the conductive post to improve mounting reliability and ease of repairing the semiconductor chip, can be easily manufactured.

In the above method of the present invention, the steps (a), (b) and (c) can be further carried out between the step (c) and the step (d). Thus, the conductive post can easily become higher.

Further, in the above device and method of the present invention, the conductive post can comprise a base-material metal layer and a joining metal layer having an ability to join with the base-material metal layer.

### BRIEF DESCRIPTION OF THE DRAWINGS

The above and other objects, advantages and features of the present invention will be more apparent from the following description taken in conjunction with the accompanying drawings, in which:

FIG. 1 is a schematic sectional view showing a flip-chip-type semiconductor device according to Embodiment 1 of the present invention;

FIGS. 2A to 2C are schematic sectional views showing the steps of the process for manufacturing the flip-chip-type semiconductor device of FIG. 1;

FIGS. 3A and 3B are schematic sectional views showing the steps of the process for manufacturing the flip-chip-type semiconductor device of FIG. 1 that follow FIG. 2C;

FIG. 4 is a schematic sectional view showing a flip-chip-type semiconductor device according to Embodiment 2 of the present invention;

FIGS. 5A to 5C are schematic sectional views showing the steps of the process for manufacturing the flip-chip-type semiconductor device of FIG. 4;

FIGS. 6A to 6C are schematic sectional views showing the steps of the process for manufacturing the flip-chip-type semiconductor device of FIG. 4 that follow FIG. 5C;

FIG. 7 is a schematic sectional view showing a flip-chip-type semiconductor device according to Embodiment 3 of the present invention;

FIG. 8 is a schematic sectional view showing a flip-chip-type semiconductor device according to Embodiment 4 of the present invention;

FIG. 9 is a schematic sectional view showing a flip-chip-type semiconductor device according to Embodiment 5 of the present invention;

FIG. 10 is a schematic sectional view showing a flip-chip-type semiconductor device according to Embodiment 6 of the present invention;

FIG. 11 is a schematic sectional view showing a flip-chip-type semiconductor device according to Embodiment 7 of the present invention;

FIGS. 12A to 12D are schematic sectional views showing the steps of the process for manufacturing the flip-chip-type semiconductor device of FIG. 11;

FIG. 13 is a schematic sectional view showing a flip-chip-type semiconductor device according to Embodiment 8 of the present invention;

FIG. 14 is a schematic sectional view showing a conventional flip-chip-type semiconductor device;

FIG. 15 is a schematic sectional view showing the flip-chip-type semiconductor device of FIG. 14 in the state of being mounted on a mounting substrate; and

FIG. 16 is a schematic sectional view showing a general repair method.

### DESCRIPTION OF THE PREFERRED EMBODIMENTS

The present invention will be now described herein with reference to illustrative embodiments. Those skilled in the art will recognize that many alternative embodiments can be accomplished using the teachings of the present invention, and that the invention is not limited to the embodiments illustrated for explanatory purposes.

(Embodiment 1)

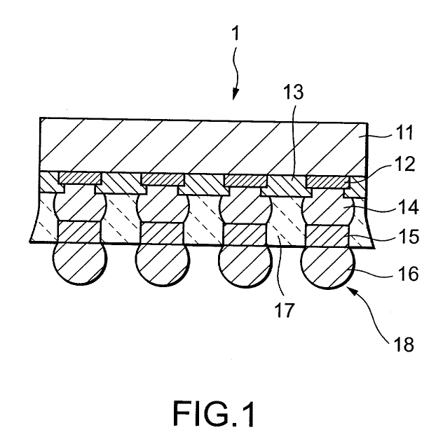

As FIG. 1 shows, a flip-chip-type semiconductor device 1 of Embodiment 1 of the present invention comprises a semiconductor chip 11 having a plurality of pad electrodes 12 on the surface thereof, connecting terminals 18 acting as connecting members for mechanically and electrically connecting the semiconductor chip 11 to a mounting substrate (not shown), and an insulating resin layer 17 covering the surface of the semiconductor chip 11.

The pad electrodes 12 of the semiconductor chip 11 are arranged in an area-array pattern on the surface of the semiconductor chip 11. The surface of the semiconductor chip 11 is covered with a passivation film 13. The passivation film 13 is adopted to protect the active region (not shown) on the surface of the semiconductor chip 11, and is formed of an organic material or an SiO (silicon oxide)-based inorganic material. The pad electrodes 12 are exposed out of the passivation film 13.

The connecting terminals 18 are constituted of conductive solder bumps 14 formed on the pad electrodes 12, metal posts 15 an end surface (upper surface) whereof are joined to the solder bumps 14, and solder electrodes 16 formed on the other end surface (lower surface) of the metal posts 15.

The solder bumps 14 are composed of a solder made of a Pb-Sn alloy, and have a spherical or hemispherical shape. The solder bumps 14 are mechanically and electrically connected to the pad electrodes 12. Alternatively, an Sn—Ag-based alloy can be used as the material for the solder bumps 14.

While the metal posts 15 have a substantially rectangular cross-sectional shape, it is to be noted that each of the metal posts 15 is substantially circular in plan view. As the material for forming the metal posts 15, a metal having high wettability to the solder, such as Cu and Ni, can be used.

The solder electrodes 16 are composed of a solder made of a Pb—Sn alloy, and have a spherical shape. The solder electrodes 16 are electrically connected to the solder bumps 14 through the metal posts 15.

The insulating resin layer 17 covers the exposed surface of the solder bumps 14 as well as the circumferential surfaces of the metal posts 15. The lower surfaces of the metal posts 15 are exposed out of the insulating resin layer 17.

The insulating resin layer 17 contains any of an epoxy-based resin, a silicone-based resin, a polyimide-based resin, a polyolefin-based resin, a cyanate-ester-based resin, a phenolic resin, a naphthalene-based resin, and fluorine-based resin as the main component thereof. Therefore, the insulating resin layer 17 has a function to disperse heat and stress applied to the semiconductor chip 11 and the passivation film 13.

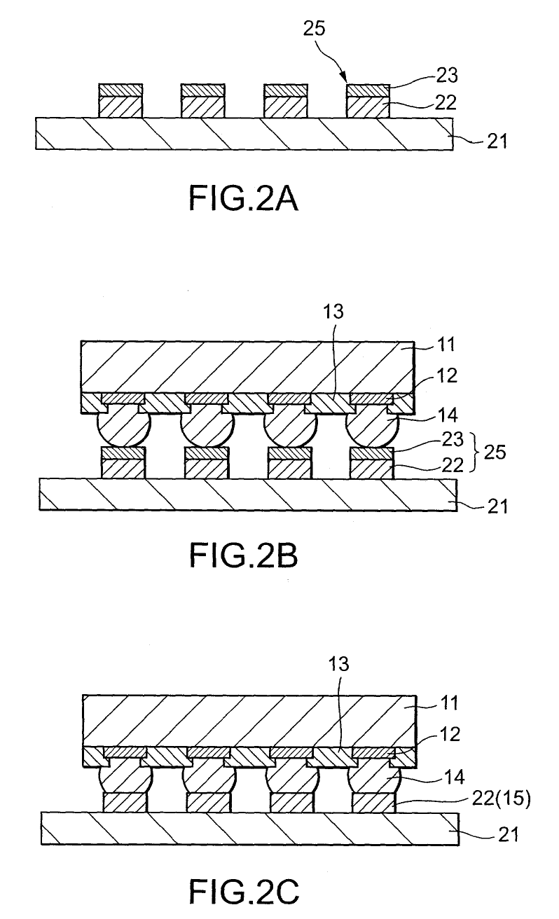

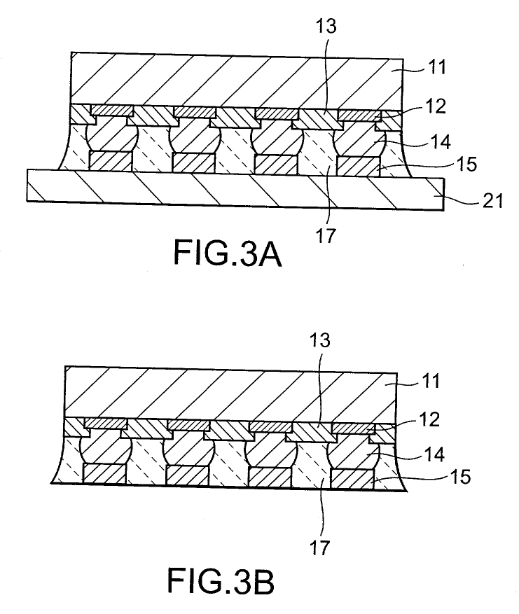

Next, a method for manufacturing the semiconductor device 1 of FIG. 1 will be described with FIGS. 2A to 2C and FIGS. 3A and 3B.

First, a semiconductor chip 11 having a plurality of pad electrodes 12 on the surface thereof, having solder bumps 14 of a high melting point formed on the pad electrodes 12, and covered with a passivation film 13 on the surface is previously prepared.

Next, a base material (temporary substrate) 21 composed of a polyimide sheet processed to a predetermined shape is prepared, the surface thereof is suitably roughened by blasting or the like, and fine Pd (palladium) particles are sprayed on the surface of the base material 21. Then, a resist layer is formed on the surface of the base material 21, and the formed resist layer is patterned to a predetermined shape to form a mask (not shown). Thereafter, a base-material metal layer 22 consisting of a metal having high wettability to the solder, such as Cu and Ni is formed by plating. In this plating step, previously sprayed Pd particles become the seed of plating. Next, a high-melting-point solder layer 23 made of a Pb—Sn alloy is formed on the base-material metal layers 22. Furthermore, the resist film is removed, and the base-material metal layers 22 and the solder layers 23 are patterned. Thus, as FIG. 2A shows, a plurality of metal-post assemblies 25 constituted of the base-material metal layers 22 and the solder layers 23, and arranged corresponding to each of a plurality of pad electrodes 12 of the semiconductor chip 11, are formed on the base material 21.

As the material for the base material 21, an organic material other than polyimide or a metal-based material can also be used if it is a material that can mechanically and easily separate the base material 21 from the base-material metal layers 22.

Next, the surface of the above-described semiconductor chip 11 is made to face the surface of the base material 21, and the pad electrodes 12 (i.e., solder bumps 14) are aligned to the metal-post assemblies 25. Thereafter the semiconductor chip 11 is placed on the base material 21 as FIG. 2B shows.

Then, as FIG. 2C shows, the solder layers 23 are melted and solidified by a heating/compressing process or a reflow process, and the base-material metal layers 22 are joined to the solder bumps 14. In this time, the solder layers 23 of the metal-post assemblies 25 are fused with the solder bumps 14. As a result, metal posts 15 are formed from remaining the base-material metal layers 22.

Since the base-material metal layers 22 have an excellent wettability to solder, the base-material metal layers 22 can be joined easily to the solder bumps 14 by melting and solidifying the solder layers 23. Thus, the conductive post is formed by the metal layer 15 and the solder bump 14 that is bulged to have an area which is larger in plan view than the area of the metal layer 15.

Next, as FIG. 3A shows, an insulating resin layer 17 is formed between the passivation film 13 and the base material 21. The insulating resin layer 17 is formed by supplying the resin along the side of the semiconductor chip 11, and allowing the resin to permeate between the semiconductor chip 11 and the base material 21 by surface tension. The exposed surfaces of the solder bumps 14 and the circumferential surfaces of the metal posts 15 are covered with the formed insulating resin layer 17.

Next, as FIG. 3B shows, the base material 21 is mechanically separated and removed to expose the lower surfaces of the metal posts 15.

Finally, solder electrodes 16 are formed on the exposed lower surfaces of the metal posts 15. The solder electrodes 16 are formed from a solder having a lower melting point than the melting points of the solder bumps 14 and the solder layers 23. Alternatively, before solder electrodes 16 are formed, a thin film of a metal such as Au and an Ni—Au alloy may be formed on the lower surfaces of the metal posts 15 using electroless plating. In this case, the adhesive force of the solder electrodes 16 to the metal posts 15 increases, and the fixability of the solder electrodes 16 is improved.

Thus, the semiconductor device 1 of FIG. 1 is manufactured.

In the flip-chip-type semiconductor device 1 according to Embodiment 1 of the present invention, as described above, the connecting terminals 18 for mechanically and electrically connecting the semiconductor chip 11 to the mounting substrate are constituted by solder bumps 14, metal posts 15, and solder electrodes 16. Therefore, the height of the connecting terminals 18, that is the standoff height of the semiconductor chip 11 to the mounting substrate (distance between the mounting substrate 21 and the semiconductor chip 11), becomes large. Therefore, stress acting to each of connecting portions between the connecting terminals 18 and each of the semiconductor chip 11 and the mounting substrate is reduced, and mounting reliability is improved. Moreover, since the use of a ceramic material as the mounting substrate, or the intervention of an under-fill resin between the semiconductor chip 11 and the mounting substrate is not required, the costs can be reduced.

Also, since the solder electrodes are not covered by the insulating resin layer, the chip 11 is repairable. And since the standoff height of the semiconductor chip 11 is large, the damage of the semiconductor chip 11 or the passivation film 13 during the repair of the semiconductor device 1 can be minimized. Therefore, since the semiconductor chip 11 is less likely to be damaged, and the percentage of the reuse of the removed semiconductor chip 11 increases, the cost can further be reduced.

Also, two layers of conductors, solder bumps 14 and metal posts 15, connect the pad electrodes 12 of the semiconductor chip 11 to the solder electrodes 16 electrically. Therefore, by adequately changing the materials of the solder bumps 14 and the metal posts 15 to meet the thermal expansion of each of the semiconductor chip 11 side and the mounting substrate side, stress can further be relieved. Further, thermal expansion can also be adjusted by changing not only the material, but also, the diameter of each of the solder bumps 14 and the metal posts 15.

Furthermore, the surface of the semiconductor chip 11 is covered with the insulating resin layer 17. The insulating resin layer 17 has the function of dispersing heat and stress applied to the semiconductor chip 11 and the passivation film 13. Therefore, mounting reliability and the ease of repairing can further be improved.

Incidentally, as described above, the solder electrodes 16 use a solder having a lower melting point then the melting point of the solder bumps 14. Therefore, since the solder electrodes 16 melt first, when heat is applied from the semiconductor chip 11 side, or the semiconductor chip 11 side and the mounting substrate side during repairing, repair can be carried out without melting the solder bumps 14.

Also, in the manufacturing method according to Embodiment 1 of the present invention, a semiconductor device 1 can be manufactured easily. Moreover, since the base material 21 is formed from a material that can easily be separated mechanically from the base-material metal layers 22, the workability is improved, and processing time can be reduced. Therefore, the manufacturing costs can be reduced.

(Embodiment 2)

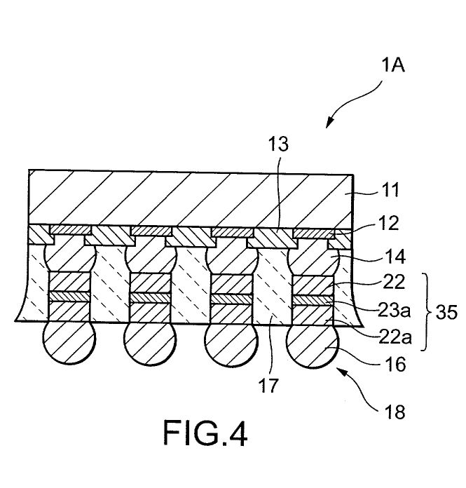

As FIG. 4 shows, the flip-chip-type semiconductor device 1A according to Embodiment 2 of the present invention is the same as the flip-chip-type semiconductor device 1 of Embodiment 1, except that each of the metal posts 35 comprises two base-material metal layers 22 and 22a laminated sandwiching a solder layer 23a. Therefore, in FIG. 4, the same constituents as in the semiconductor device 1 of Embodiment 1 are denoted by the same reference numerals, and the description thereof will be omitted.

In the semiconductor device 1A, each of the base-material metal layers 22 and 22a are joined by the solder layer 23a intervening between them, and each of the metal posts 35 is formed from a base-material metal layer 22, a solder layer 23a, and a base-material metal layer 22a.

As a material for forming the base-material metal layers 22a, a metal having an excellent wettability to solder, such as Cu and Ni, is used similarly to the base-material metal layers 22. As a material for forming the solder layers 23a, a Pb—Sn alloy is used similarly to the solder layers 23.

The solder bumps 14 and the solder layers 23a, are formed of a high-melting-point solder, and the solder electrodes 16 are formed of a solder having a lower melting point than the melting point of the solder bumps 14 and the solder layers 23a.

Next, a method for manufacturing a semiconductor device 1A shown in FIG. 4 will be described.

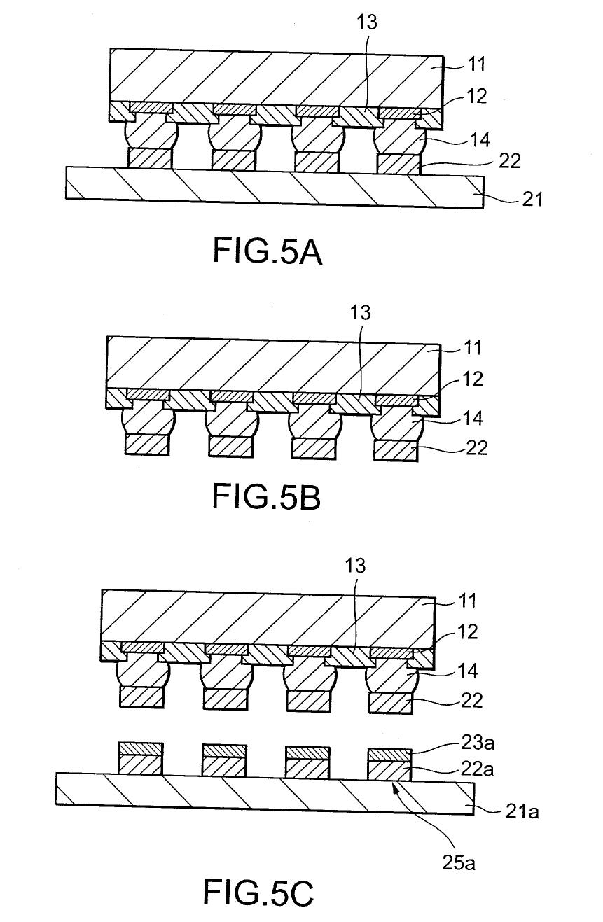

First, the state shown in FIG. 5A is formed through the processes of FIG. 2 in the same manner as the semiconductor device 1 of Embodiment 1.

Next, as FIG. 5B shows, the base material 21 is mechanically separated from the base-material metal layers 22 to expose the lower surface of the base-material metal layers 22.

Thereafter, as FIG. 5C shows, a plurality of metal-post assemblies 25a each composed of a base-material metal layer 22a and a solder layer 23a formed thereon, and arranged corresponding to each of a plurality of pad electrodes 12 of the semiconductor chip 11 is formed on the base material 21a in the same manner as the process of FIG. 2A.

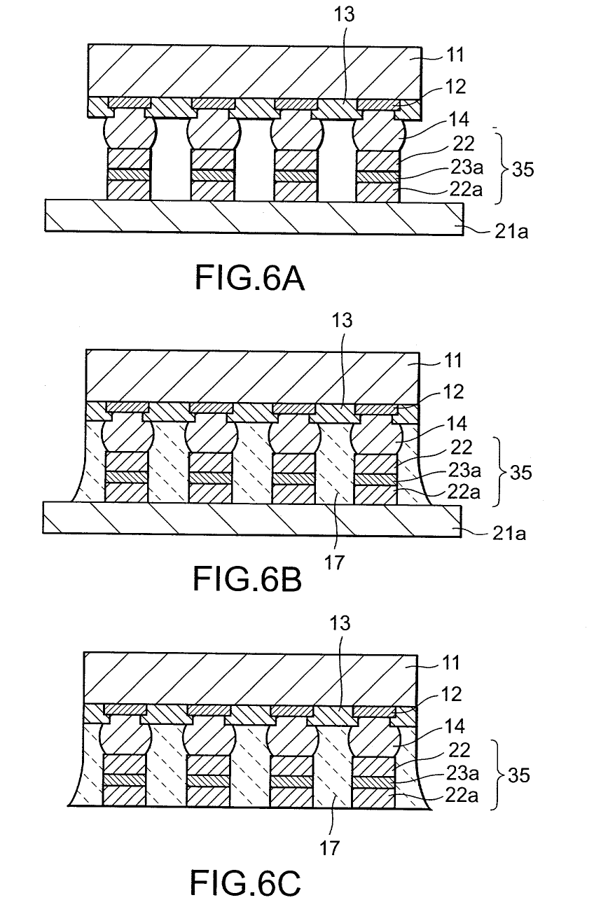

Next, the surface of the semiconductor chip 11 is made to face the surface of the base material 21a, and the pad electrodes 12 (i.e., base-material metal layer 22) are aligned to the metal-post assemblies 25a. Thereafter, as FIG. 6A shows, the semiconductor chip 11 is placed on the base material 21a. Then, the solder layers 23a are melted and solidified by a heating/compressing process or a reflow process, and the base-material metal layers 22a are joined to the lower surfaces of the base-material metal layers 22. Thus, metal posts 35 each composed of a base-material metal layer 22, a solder layer 23a, and a base-material metal layer 22a are formed.

Since the base-material metal layers 22 and 22a have an excellent wettability to solder, the base-material metal layers 22a can be joined to the base-material metal layers 22 easily by melting and solidifying the solder layers 23a. That is, the base-material metal layers 22 can be laminated with the base-material metal layers 22a easily.

Thereafter, as FIG. 6B shows, an insulating resin layer 17 is formed between the passivation film 13 and the base material 21a. The exposed surfaces of the solder bumps 14 and the circumferential surfaces of the metal posts 35 are covered with the formed insulating resin layer 17.

Next, as FIG. 6C shows, the base material 21a is mechanically separated from the metal posts 35 to expose the lower surfaces of the metal posts 35.

Finally, the solder electrodes 16 are formed on the exposed lower surfaces of the metal posts 35.

Thus, the semiconductor device 1A of FIG. 4 is manufactured.

In the flip-chip-type semiconductor device 1A according to Embodiment 2 of the present invention, as described above, since the metal posts 35 each comprises a base-material metal layers 22 and 22a laminated sandwiching a solder layer 23a, the height of the connecting terminals 18, that is the standoff height of the semiconductor chip 11 to the mounting substrate becomes larger. Therefore, mounting reliability and the ease of repairing are further improved than the semiconductor device 1 of Embodiment 1.

Also, in the manufacturing method according to Embodiment 2 of the present invention, a semiconductor device 1A can be manufactured easily. Moreover, since the base materials 21 and 21a are formed from a material that can easily be separated mechanically from the base-material metal layers 22 and 22a, the workability is improved, and processing time can be reduced. Therefore, the standoff height of the semiconductor chip 11 can be increased without increasing the manufacturing costs.

(Embodiment 3)

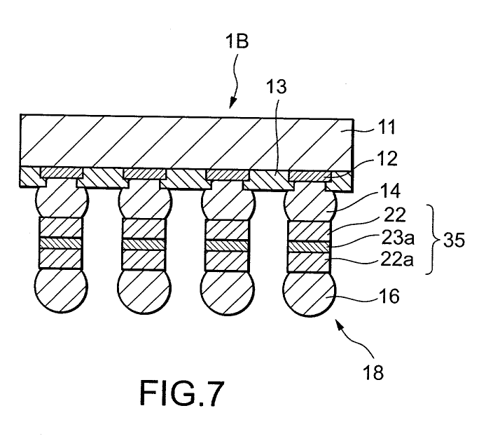

As FIG. 7 shows, the flip-chip-type semiconductor device 1B according to Embodiment 3 of the present invention is the same as the flip-chip-type semiconductor device 1A of Embodiment 2, except that no insulating resin layer 17 is formed. Therefore, in FIG. 7, the same constituents as in the semiconductor device 1A of Embodiment 2 are denoted by the same reference numerals, and the description thereof will be omitted.

If the standoff height of the semiconductor chip 11 to the mounting substrate is high enough to achieve desired mounting reliability and the ease of repairing, that is, if a sufficient resistance to stress can be achieved, the formation of the insulating resin layer 17 is not required as in this embodiment.

Therefore, in the flip-chip-type semiconductor device 1B of Embodiment 3, since the step for forming the insulating resin layer 17 (i.e., the step shown in FIG. 6(c)) can be eliminated from the process manufacturing the flip-chip-type semiconductor device 1A of Embodiment 2, the manufacturing costs can be reduced advantageously.

The solder electrodes 16 are formed from a solder having a lower melting point than the melting point of the solder bumps 14 and the solder layers 23a. Therefore, by applying heat of a temperature to melt the solder electrodes 16 but not to melt the solder bumps 14 and the solder layers 23a, the semiconductor device 1B can be separated from the mounting substrate at the solder electrodes 16 during repairing.

(Embodiment 4)

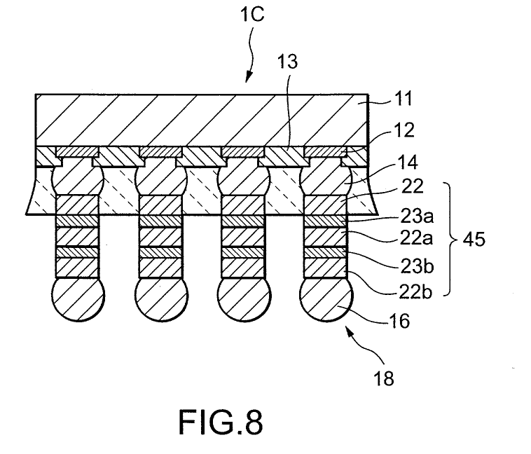

As FIG. 8 shows, the flip-chip-type semiconductor device 1C according to Embodiment 4 of the present invention is the same as the flip-chip-type semiconductor device 1 of Embodiment 1, except the metal posts 45 each comprising three base-material metal layers 22, 22a, and 22b laminated with two intervening solder layers 23a and 23b. Therefore, in FIG. 8, the same constituents as in the semiconductor device 1 of Embodiment 1 are denoted by the same reference numerals, and the description thereof will be omitted.

In the semiconductor device 1C, the base-material metal layers 22 and 22a are joined by solder layers 23a intervening between them. Also, the base-material metal layers 22a and 22b are joined by solder layers 23b intervening between them. And the base-material metal layers 22, 22a, and 22b, and the solder layers 23a and 23b form the metal posts 45.

As a material for forming the base-material metal layers 22b, a metal having an excellent wettability to solder such as Cu and Ni is used, as in the base-material metal layers 22 and 22a. As a material for forming the solder layers 23b, a Pb—Sn alloy is used, as in the solder layers 23 and 23a.

The solder electrodes 16 are formed from a solder having a lower melting point than the melting point of the solder bumps 14 and the solder layers 23a and 23b.

Also, the insulating resin layer 17 covers the exposed surface of the solder bumps 14, as well as a part of the circumferential surfaces of the metal posts 45 (i.e., only the circumferential surfaces of the base-material metal layers 22).

The method for manufacturing the semiconductor device 1C will be apparent from the above-described manufacturing methods in Embodiments 1 and 2. That is, after carrying out the steps shown in FIGS. 2 and 3, the steps equivalent to the steps shown in FIGS. 5C and 6A are repeated twice, and a step for forming solder electrodes 16 is carried out to form the semiconductor device 1C.

In the flip-chip-type semiconductor device 1C according to Embodiment 4, the standoff height of the semiconductor chip 11 to the mounting substrate becomes higher than the standoff height in the flip-chip-type semiconductor device 1, 1A, and 1B according to Embodiments 1, 2, and 3, respectively, and mounting reliability and the ease of repairing is further improved.

Also, since the thickness of the insulating resin layer 17 is smaller than in the flip-chip-type semiconductor device 1A according to Embodiment 2, the material costs for the insulating resin layer 17 can be reduced accordingly.

(Embodiment 5)

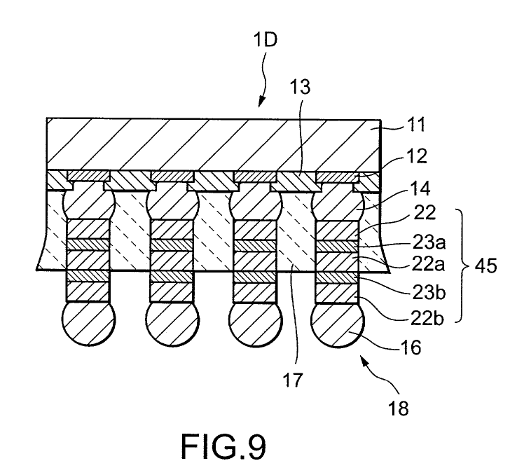

As FIG. 9 shows, the flip-chip-type semiconductor device 1D according to Embodiment 5 of the present invention is the same as the flip-chip-type semiconductor device 1C of Embodiment 4, except an insulating resin layer 17 covers the circumferential surfaces of the base-material metal layers 22 and 22a, and the solder layers 23a. Therefore, in FIG. 9, the same constituents as in the semiconductor device 1C of Embodiment 4 are denoted by the same reference numerals, and the description thereof will be omitted.

The method for manufacturing the semiconductor device 1D will be apparent from the above-described manufacturing methods in Embodiment 2. That is, after carrying out the steps shown in FIGS. 5 and 6, the steps equivalent to the steps shown in FIGS. 5C and 6A are repeated, and a step for forming solder electrodes 16 is carried out to form the semiconductor device 1D.

In the flip-chip-type semiconductor device 1D according to Embodiment 5, since each of the metal posts 45 comprises the base-material metal layers 22, 22a, and 22b laminated with solder layers 23a and 23b, as in the flip-chip-type semiconductor device 1C of Embodiment 4, the height of the metal posts 45 becomes further higher. In such case, if the entire circumferential surfaces of high metal posts 45 are covered with an insulating resin layer 17, the semiconductor chip 11 may be warped depending on the material used in the insulating resin layer 17.

On the other hand, the larger the thickness of the insulating resin layer 17, the higher the mounting reliability and the ease of repairing, that is, the higher the effect to relieve stress produced by heat.

In the flip-chip-type semiconductor device 1D of Embodiment 5, since the insulating resin layer 17 covers the circumferential surfaces of the base-material metal layers 22 and 22a, and the solder layers 23a, the effect of relieving stress is improved while inhibiting the occurrence of warp in the semiconductor chip 11.

If the warp of the semiconductor chip 11 cannot be inhibited sufficiently, only the circumferential surfaces of the base-material metal layers 22 may be covered as in the flip-chip-type semiconductor device 1C of Embodiment 4. Thus, by adequately determining the thickness of the insulating resin layer 17, the effect of inhibiting the warp of the semiconductor chip 11 and the effect of relieving stress can be optimized.

(Embodiment 6)

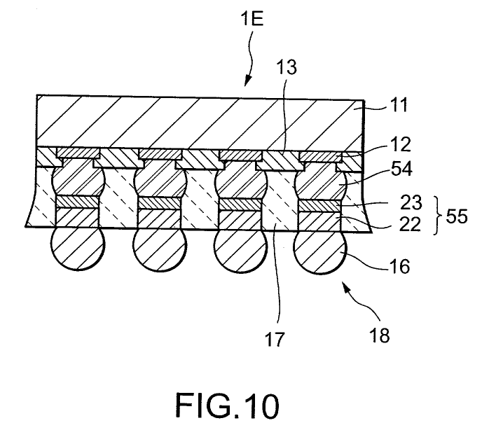

As FIG. 10 shows, the flip-chip-type semiconductor device 1E according to Embodiment 6 of the present invention is equivalent to the semiconductor device 1 of Embodiment 1 wherein the solder bumps 14 are replaced with Au (gold) bumps 54. Therefore, in FIG. 10, the same constituents as in the semiconductor device 1 of Embodiment 1 are denoted by the same reference numerals, and the description thereof will be omitted.

The semiconductor device 1E is manufactured through the manufacturing method shown in FIGS. 2 and 3 similarly to the semiconductor device 1 of Embodiment 1. In the steps shown in FIGS. 2B and 2C, when the base-material metal layers 22 are joined to the Au bumps 54, the solder layers 23 of the metal post assemblies 25 are left without being fused into the Au bumps 54. As a result, the base-material metal layers 22 and the solder layers 23 form the metal posts 55.

Since Au is a material that is deformed more easily than solder, the semiconductor device 1E of Embodiment 6 relieves stress more than the semiconductor device 1 of Embodiment 1, and mounting reliability and the ease of repairing is improved.

(Embodiment 7)

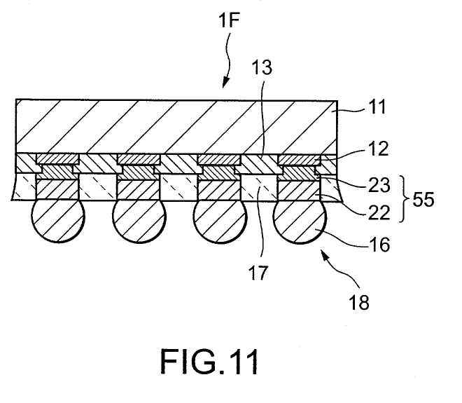

As FIG. 11 shows, the flip-chip-type semiconductor device 1F according to Embodiment 7 of the present invention is equivalent to the flip-chip-type semiconductor device 1E of Embodiment 6 where from the Au bumps 54 are omitted. Therefore, in FIG. 11, the same constituents as in the semiconductor device 1E of Embodiment 6 are denoted by the same reference numerals, and the description thereof will be omitted.

In the semiconductor device 1F, each of the base-material metal layers 22 is joined to a pad electrode 12 through a solder layer 23, and a base-material metal layer 22 and a solder layer 23 form a metal post 55.

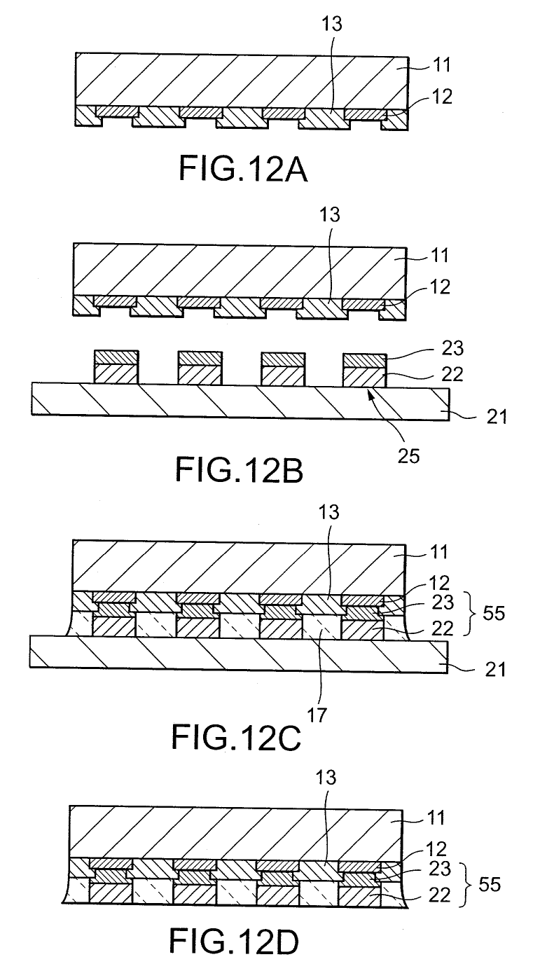

FIGS. 12A to 12D are schematic sectional views showing the steps of a method for manufacturing the semiconductor device 1F.

First, as FIG. 12A shows, a semiconductor chip 11 having a plurality of pad electrodes 12 on the surface thereof, which is covered with a passivation film 13 is previously prepared.

Next, as FIG. 12B shows, similarly to the step shown in FIG. 2B of Embodiment 1, a plurality of metal-post assemblies 25, each composed of a base-material metal layer 22 and a solder layer 23 formed thereon, and arranged corresponding to each of a plurality of pad electrodes 12 of the semiconductor chip 11, are formed on a base material 21.

Thereafter the surface of the semiconductor chip 11 is made to face the surface of the base material 21, the pad electrodes 12 are aligned so as to correspond to the metal-post assemblies 25, and then the semiconductor chip 11 is placed on the base material 21.

Next, the solder layers 23 are melted and solidified by a heating and compressing process or a reflow process, and the base-material metal layers 22 are joined to the pad electrodes 12 through the solder layers 23.

Since the base-material metal layers 22 have an excellent wettability to solder, the base-material metal layers 22 can be joined to the pad electrodes 12 easily by melting and solidifying the solder layers 23.

Next, as FIG. 12C shows, an insulating resin layer 17 is formed between the passivation film 13 and the base material 21. The exposed circumferential surfaces of the metal posts 55 (i.e., the entire circumferential surfaces of the base-material metal layers 22, and a part of the circumferential surfaces of the solder layers 23) are covered with the formed insulating resin layer 17.

Thereafter, as FIG. 12D shows, the base material 21 is mechanically separated from the metal posts 55 to expose the lower surface of the metal posts 55.

Finally, solder electrodes 16 are formed on the exposed lower surface of the metal posts 55.

Thus, the semiconductor device 1F of FIG. 11 is produced.

In the flip-chip-type semiconductor device 1F according to Embodiment 7 of the present invention, as described above, the connecting terminals 18 for mechanically and electrically connecting the semiconductor chip 11 to the mounting substrate are composed of the metal posts 55 and the solder electrodes 16. Therefore, the height of the connecting terminals 18, that is the standoff height of the semiconductor chip 11 to the mounting substrate becomes large. Therefore, as in Embodiments 1 to 6, stress acting to each of the connecting portions between the connecting terminals 18 and each of semiconductor chip 11 and the mounting substrate is reduced, and mounting reliability and the ease of repairing are improved.

According to Embodiment 7, since no solder bumps 14 or Au bumps 54 are formed, stress relieving is inferior to Embodiments 1 to 6 to some extent, the costs can be reduced by omitting the step for forming the bumps.

Also, if the pitch between a plurality of connecting terminals 18 is narrowed, the size reduction of the bumps, the elimination of lead, as well as the reduction of alpha rays are required, and the costs for forming bumps will increase. Therefore, accompanying the narrowing of the pitch between connecting terminals 18, the effect of cost reduction is further elevated.

In the semiconductor 1F of Embodiment 7, if stress relieving becomes insufficient due to the absence of solder bumps 14 or Au bumps 54, it can be compensated by increasing the standoff height of the semiconductor chip by forming metal posts comprising a plurality of base-material metal layers laminated with solder layers, as in Embodiments 2, 3, 4, and 5.

(Embodiment 8)

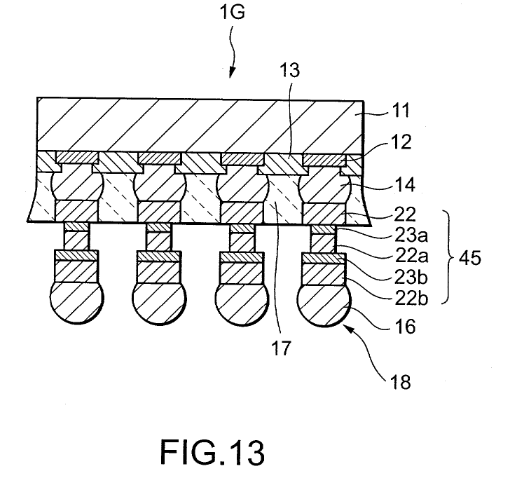

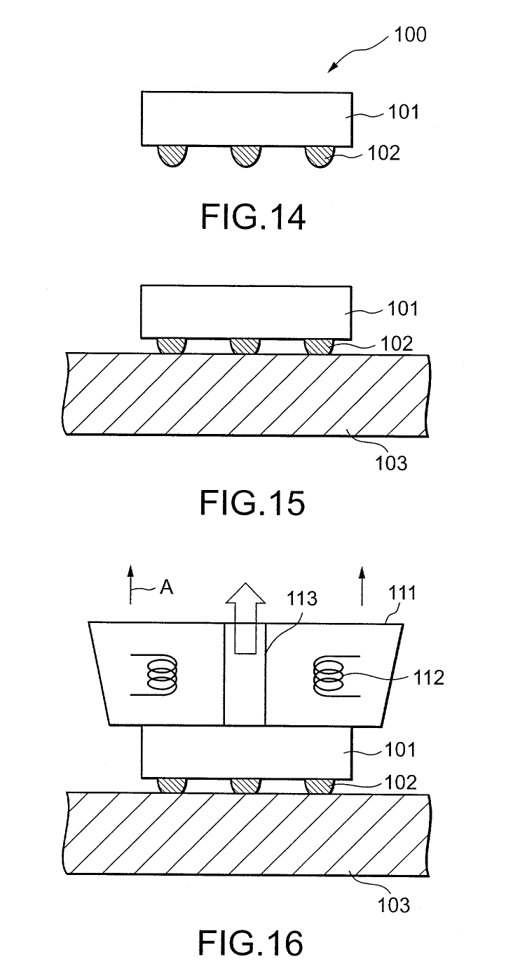

As FIG. 13 shows, the flip-chip-type semiconductor device 1G according to Embodiment 8 of the present invention is equivalent to the semiconductor device 1C of Embodiment 4 wherein the diameters of the solder layers 23a and the base-material metal layers 22a are formed to be smaller than the diameters of the base-material metal layers 22, the solder layers 23b, and base-material metal layers 22b. Therefore, in FIG. 13, the same constituents as in the semiconductor device 1C of Embodiment 4 are denoted by the same reference numerals, and the description thereof will be omitted.

As a method for further improving stress relieving, the use of thinner metal posts is considered. However, if the entire metal posts 45 are thinned, the size of the solder electrodes 16 formed on the end surfaces of the metal posts will also be reduced, resulting in lowered resistance to stress. Therefore, in Embodiment 8, only a part of the metal costs 45 is thinned, and the base-material metal layers 22b contacting the solder electrodes 16 are not thinned.

By adopting such a constitution, in the semiconductor device 1G, stress relieving can further be improved than the semiconductor device 1C of Embodiment 4.

The method for manufacturing the semiconductor device 1G of Embodiment 8 is basically the same as the method for manufacturing the semiconductor device 1C of Embodiment 4. In the first step of FIG. 6A during each of steps corresponding to FIG. 5A and FIG. 6A is repeated twice, the diameters of the base-material metal layers 22a and solder layers 23a to be formed on the base material 21a are made smaller than the diameters of the base-material metal layers 22.

In FIG. 13, although the insulating resin layer 17 covers only the exposed surfaces of solder bumps 14 and the circumferential surfaces of the base-material metal layers 22, the formation of the insulating resin layer 17 is optional, and the thickness thereof can be changed optionally.

(Alternative Embodiments)

The metal posts can be made to comprise four or more base-material metal layers laminated with intervening solder layers. Furthermore, the base-material metal layers themselves can be made laminates of a plurality of metal layers composed of the same metal or different metals.

Also, the thickness of the base-material metal layers and the solder layers can optionally determined, and the material used for the base-material metal layers are not limited to Cu or Ni. Furthermore, the solder layers may be replaced with layers consisting of a joinable metal such as Au.

According to the flip-chip-type semiconductor device and the manufacturing method thereof, as described above, stress produced in the connecting portion between the semiconductor chip and the mounting substrate is reduced, and excellent mounting reliability can be achieved while reducing the costs.

It is apparent that the present invention is not limited to the above embodiments and description, but may be changed or modified without departing from the scopes and spirits of apparatus claims that are indicated in the subsequent pages as well as methods that are indicated below:

AA. A method for manufacturing a semiconductor device comprising:

(a) selectively forming conductive post on a base material,

(b) placing a semiconductor chip having a pad electrode on the surface thereof so that said pad electrode faces one end surface of said conductive post to electrically connect said pad electrode to said conductive post,

(c) separating said base material from said conductive post to expose the other end surface of said conductive post, and

(d) forming a bump electrode on said exposed other end surface of said conductive post.

BB. The method according to Method AA, wherein a conductive bump is formed on said pad electrode, and in said step (b), said conductive bump is joined to said conductive post.

CC. The method according to Method AA, wherein said conductive post comprises a base-material metal layer and a joining metal layer having an ability to join with said base-material metal layer.

DD. The method according to Method AA, wherein said steps (a), (b) and (c) are further carried out between said step (c) and said step (d).

EE. The method according to Method DD, wherein said conductive post comprises at least two base-material metal layer and a joining metal layer having an ability to join with said base-material metal layers, and said base-material metal layers are laminated through said joining metal layer.

FF. The method according to Method CC, wherein said joining metal layer is formed of solder, and said base-material metal layer is formed of a metal having wettability to solder.

GG. The method according to Method EE, wherein said joining metal layer is formed of solder, and each of said base-material metal layers is formed of a metal having wettability to solder.

HH. The method according to Method AA, further comprising forming an insulating resin layer that covers said surface of said semiconductor chip while covering at least a part of the circumferential surface of said conductive post between said step (b) and said step (c).

II. The method according to Method BB, wherein said conductive bump is composed of solder, said conductive post comprises a solder layer, and in said step (b), said conductive bump is fused to said solder layer of said conductive post.

JJ. The method according to Method BB, wherein said conductive bump is composed of Au.

What is claimed is:

1. A semiconductor device comprising:
a semiconductor chip having pad electrode selectively formed on the surface thereof,
a conductive post provided on said pad electrode, and
a bump electrode formed on one end surface of said conductive post,
said conductive post comprising at least first and second conductive layers, and said first conductive layer being composed of a different material from the material of said second conductive layer.

2. The device according to claim 1, wherein said conductive post comprises a conductive bump provided on said pad electrode.

3. The device according to claim 1, wherein said conductive post comprises a base-material metal layer and a joining metal layer having an ability to join with said base-material metal layer.

4. The device according to claim 1, wherein said conductive post comprises at least two base-material metal layers and a joining metal layer having an ability to join with said base-material metal layers, said base-material metal layers are laminated through said joining metal layer.

5. The device according to claim 3, wherein said joining metal layer is formed of solder, and said base-material metal layer is formed of a metal having wettability to solder.

6. The device according to claim 4, wherein said joining metal layer is formed of solder, and each of said base-material metal layers is formed of a metal having wettability to solder.

7. The device according to claim 1, further comprising an insulating resin layer that covers said surface of said semiconductor chip while covering at least a part of the circumferential surface of said conductive post.

8. The device according to claim 2, wherein said conductive bump is composed of one of solder and Au.

9. The device according to claim 1, wherein said conductive post comprises at least three, first, second and third parts, which are piled in the direction of length of said conductive post, and a diameter of said second part is smaller than diameters of said first and third parts.

10. The device according to claim 9, wherein said second part is sandwiched between said first and third parts.

11. The device according to claim 1, wherein said first conductive layer comprises a first solder and said bump electrode comprises a second solder, and said second solder is lower in melting point than said first solder.

12. A semiconductor device comprising a semiconductor chip, a plurality of pad electrodes formed on said semiconductor chip, a plurality of bump electrodes, and a plurality of conductive posts each intervening between an associated one of said electrode pads and an associated one of said bump electrodes to form an electrical path therebetween, each of said conductive posts including a first conductive layer and a second conductive later that is bulged to have an area which is larger in plan view than an area of said first conductive layer.

13. The device as claimed in claim 12, wherein said first conductive layer is provided on a side of the bump electrode and said second conductive layer is provided on a side of the electrode pad.

14. The device as claimed in claim 13, wherein said first conductive layer comprises a plurality of metal layers which are stacked with each other.

15. The device as claimed in claim 13, wherein said first conductive layer comprises a first metal layer and said second conductive layer comprises a first solder.

16. The device as claimed in claim 15, wherein said bump electrode comprises a second solder that is lower in melting point than said first solder.

17. The device as claimed in claim 16, wherein said first conductive layer comprises at least one additional metal layer that is stacked with said first metal layer.

18. A semiconductor device comprising a semiconductor chip, a plurality of pad electrodes formed on said semiconductor chip, a plurality of bump electrodes, and a plurality of conductive posts each intervening between an associated one of said electrode pads and an associated one of said bump electrodes to form an electrical path therebetween, each of said conductive posts including a first solder layer and a first metal layer.

19. The device as claimed in claim 18, wherein said first metal layer is provided on a side of the bump electrode and said first solder layer is provided on a side of the electrode pad, each of said bump electrode comprising a second solder that is lower in melting point than said first solder layer.

20. The device as claimed in claim 18, wherein each of said conductive posts further includes at least one second metal layer that is stacked with said first metal layer.
